(19) United States
(12) Patent Application Publication
(10) Pub. No.: US 2026/0136786 A1
(43) Pub. Date: May 14, 2026

(54) TRANSPARENT DISPLAY DEVICE

(71) Applicant: LG Display Co., Ltd., Seoul (KR)

(72) Inventors: Hoi Yong KWON, Paju-si (KR); Gyu Jae YOHN, Paju-si (KR)

(73) Assignee: LG Display Co., Ltd., Seoul (KR)

(21) Appl. No.: 19/346,206

(22) Filed: Sep. 30, 2025

(30) Foreign Application Priority Data
Nov. 13, 2024 (KR) 10-2024-0161211

(51) Int. Cl. H10K 59/131; H10K 59/127; H10K 59/38; H10K 59/80; H10K 59/88; H10K 102/00

(52) U.S. Cl. CPC H10K 59/131; H10K 59/127; H10K 59/38; H10K 59/8792; H10K 59/88; H10K 2102/351

(57) ABSTRACT

Disclosed is a transparent display device including a first substrate having an active area comprising an emission area and a transmission area, and a non-active area around the active area, a plurality of power voltage lines spaced apart from the transmission area within the active area of the first substrate, a light emitting element at the emission area, an island structure provided on each of the plurality of power voltage lines and spaced apart from at least an intermediate layer of the light emitting element, a second substrate facing the first substrate and a spacer located on at least a portion of the island structure, and provided between the first substrate and the second substrate.

This application claims the benefit of Korean Patent Application No. 10-2024-0161211, filed on Nov. 13, 2024, which is hereby incorporated by reference as if fully set forth herein.

### BACKGROUND

### Field of the Disclosure

The present disclosure relates to a transparent display device and, more particularly, to a display device enabling transparent display.

### Discussion of the Related Art

A display device includes a plurality of subpixels within a display panel and includes various wirings and transistors for driving the subpixels.

Display devices are being developed to meet various needs, and research is currently being conducted on transparent display devices capable of displaying information while allowing objects or images behind the display device to be visible therethrough.

Further, a transparent display device includes transmission areas. However, since the transmission areas typically do not overlap wirings and transistors, it is difficult to increase the dimensions of the transmission areas.

### SUMMARY OF THE DISCLOSURE

Accordingly, the present disclosure is directed to a transparent display device that substantially obviates one or more problems due to limitations and disadvantages of the related art.

A technical task of a transparent display device according to embodiments of the present disclosure is to increase transmittance.

Another technical task of a transparent display device according to embodiments of the present disclosure is to simultaneously reduce a cell gap within an active area and prevent or suppress non-filling or overfilling of the cell gap.

Another technical task of a transparent display device according to embodiments of the present disclosure is to prevent, reduce, or minimize influence of a crack in a component in contact with a spacer structure on surrounding components.

Another technical task of a transparent display device according to embodiments of the present disclosure is to reduce the width and thickness of a spacer structure that maintains a gap between substrates facing each other.

Another technical task of a transparent display device according to embodiments of the present disclosure is to reduce the width of a cell gap maintaining means to increase the dimensions of a transmission area.

A further technical task of a transparent display device according to embodiments of the present disclosure is to prevent or reduce an increase in the number of masks or reduce the number of masks so as to achieve process optimization.

Additional advantages, aspects, and features of the disclosure will be set forth in part in the description which follows and in part will become apparent to those having ordinary skill in the art upon examination of the following description or may be learned from practice of the disclosure. The aspects and other advantages of the disclosure may be realized and attained by the structure particularly pointed out in the written description and claims hereof as well as the appended drawings.

A transparent display device according to an example embodiment of the present disclosure may have a uniformly reduced cell gap in an active area.

To achieve these aspects and other advantages and in accordance with the purpose of the disclosure, as embodied and broadly described herein, a transparent display device includes a first substrate having an active area comprising an emission area and a transmission area, and a non-active area around the active area, a plurality of power voltage lines spaced apart from the transmission area within the active area of the first substrate, a light emitting element at the emission area, an island structure provided on each of the plurality of power voltage lines and spaced apart from at least an intermediate layer of the light emitting element, a second substrate facing the first substrate and a spacer located on at least a portion of the island structure, and provided between the first substrate and the second substrate.

It is to be understood that both the foregoing general description and the following detailed description of the present disclosure are by way of example and explanatory and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this application, illustrate example embodiment(s) of the present disclosure and together with the description serve to explain the principle of the disclosure. In the drawings:

FIG. 1 is a plan view showing a transparent display device according to an example embodiment of the present disclosure;

FIG. 2 is a circuit diagram showing one example of a subpixel of FIG. 1;

FIG. 3 is an enlarged view of region A of FIG. 1 according to an example embodiment of the present disclosure;

FIG. 4 is a cross-sectional view taken along line I-I′ in FIG. 3;

FIG. 5 is a plan view showing upper and lower structures corresponding to a spacer of FIG. 4;

FIG. 6 is a plan view showing a spacer structure formed of an upper substrate structure and an adjacent upper substrate structure;

FIG. 7 is a plan view showing a transparent display device according to a first example embodiment of the present disclosure;

FIG. 8 is a plan view showing a transparent display device according to a second example embodiment of the present disclosure; and

FIG. 9 is a cross-sectional view taken along line II-II′ and line III-III′ in FIG. 7 or FIG. 8 together.

### DETAILED DESCRIPTION

Hereinafter, example embodiments of the present disclosure will be described with reference to the accompanying drawings. Throughout the description, the same reference numerals refer to substantially the same components. In the following description, if a detailed description of known technology or configuration related to the present disclosure may unnecessarily obscure the features of the present disclosure, the detailed description of such known technology or configuration may be omitted. In addition, component names used in the following description are selected in consideration of the ease of preparing the description and may differ from the names of parts of an actual product.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless a more limiting term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless a more limiting term like “immediate(ly)” or “direct(ly)” or “close(ly) is used. It should be understood that, where an element or layer is referred to as being “connected to”, or “coupled to” another element or layer, it can be directly connected to or coupled to the other element or layer, or one or more intervening elements or layers can be present.

In the description of the various example embodiments of the present disclosure, where such terms as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, such terms as “first” and “second” can be used to describe a variety of components. These terms aim to refer to the same or similar components separately from one another and do not limit the components. Accordingly, throughout the specification, a “first” component can be the same as a “second” component, and vice versa, within the technical concept of the present disclosure, unless specifically mentioned otherwise.

Features of various embodiments of the present disclosure can be partially or wholly coupled to or combined with each other, and can be variously inter-operated with each other and driven technically as those skilled in the art can sufficiently understand. The embodiments of the present disclosure can be carried out independently from each other, or can be carried out together in a co-dependent relationship.

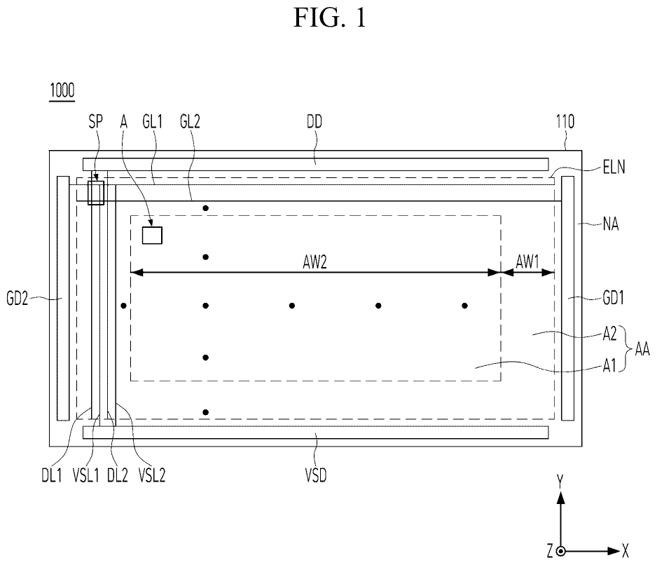

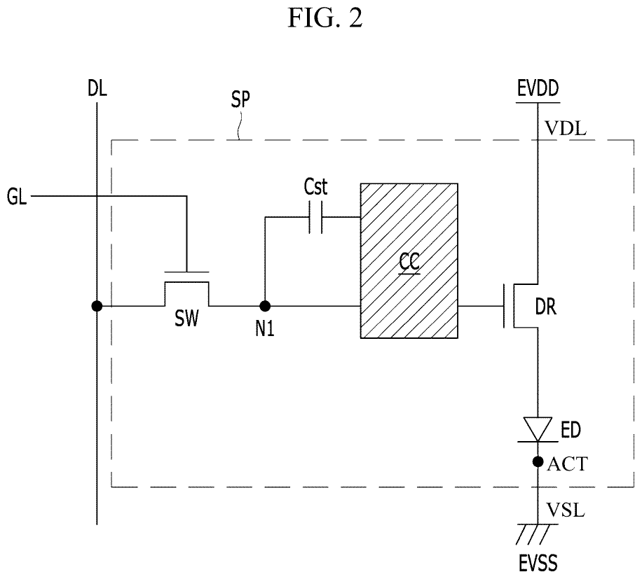

FIG. 1 is a plan view showing a transparent display device according to an example embodiment of the present disclosure, and FIG. 2 is a circuit diagram showing one example of a subpixel of FIG. 1.

As illustrated in FIGS. 1 and 2, a transparent display device 1000 according to an example embodiment of the present disclosure includes a display panel 110, and the display panel 110 includes an active area AA and a non-active area NA surrounding the active area AA.

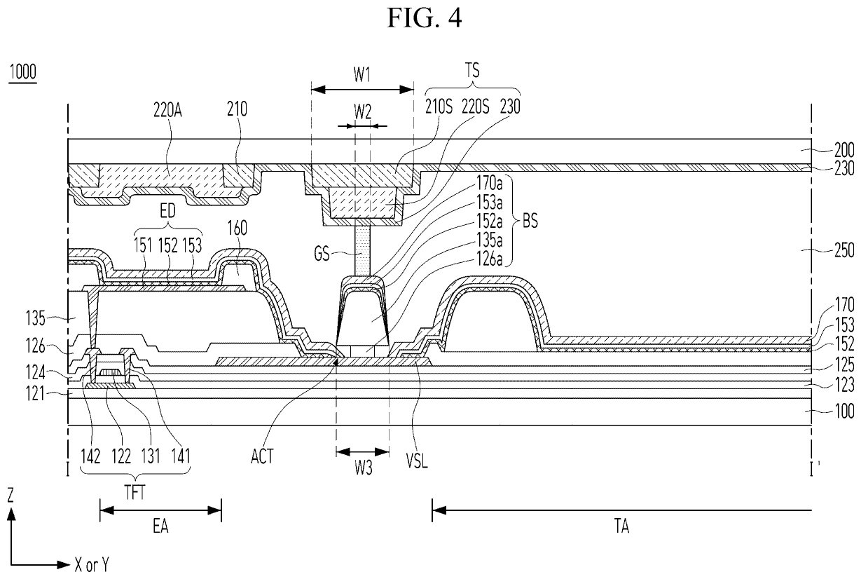

The display panel 110 may include first and second substrates 100 and 200 (in FIG. 4) that face each other, and components between the first and second substrates 100 and 200.

The transparent display device 1000 may include the display panel 110 and a case (not shown) that accommodates side surfaces of the display panel 110 and a lower portion of the display panel 110. The non-active area NA of the display panel 110 may be shielded by the case or covered by a separate printed film. A printed circuit film and/or a battery may be provided between the lower portion of the display panel 110 and the case.

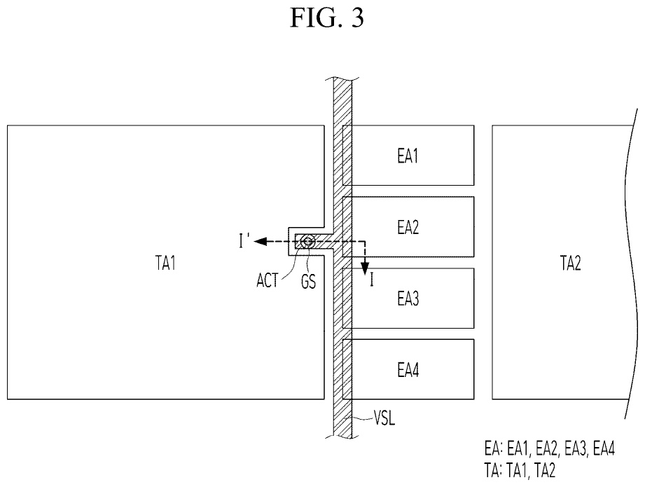

An area where a plurality of subpixels SP are arranged may be the active area AA, and an area other than the active area AA may be the non-active area NA. The transparent display device 1000 may have transmission areas within the subpixels SP or may have transmission areas spaced apart from the subpixels SP. The specific configuration of the transmission areas will be described later with reference to the drawings of FIG. 3 and therebelow.

The non-active area NA may be disposed in an edge area surrounding the active area AA that displays an image. At least one driver, e.g., gate drivers GD1, GD2, and a data driver DD for driving the plurality of subpixels SP may be disposed at the non-active area NA.

In addition to the above-described drivers GD1, GD2, and DD, additional elements including various wirings for driving the subpixels SP within the active area AA may be further disposed in the non-active area NA.

The active area AA includes a first area A1, also referred to as a central area, located at the center of the active area AA and a second area A2 located between an edge of the first area A1 and an edge line ELN of the active area AA. The second area A2 is located within a first distance AW1 from the edge line ELN of the active area AA and occupies a first active width which is equal to the first distance AW1.

The first area A1 may have a greater distance from the edge line ELN of the active area AA than the first distance AW1. A second distance AW2 occupied by the first area A1 in the active area AA occupies a larger width than the first distance AW1 occupied by the second area A2.

According to embodiments of the present disclosure, only the second area A2 may be used as an area supporting a cell gap between the first and second substrates 100 and 200, or the entire active area AA may be used as the area supporting the cell gap between the first and second substrates 100 and 200.

At least the second area A2 within the active area AA may include spacers supporting the cell gap between the first and second substrates 100 and 200. The spacers GS (in FIG. 3) may be disposed only in the second area A2 of the active area AA. Alternatively, the spacers GS may be evenly disposed in the entire active area AA, that is, the first and second areas A1 and A2.

The entire active area AA includes the plurality of subpixels SP, and each of the subpixels SP may include, for example, a pixel circuit, as shown in FIG. 2. The subpixels SP may be arranged in both the first area A1 and the second area A2. The plurality of subpixels SP may be arranged at equal intervals.

In addition, as shown in FIG. 1, the drivers GD1, GD2, and DD may be included in the non-active area NA so as to be connected to various wirings in the active area AA. Specifically, the gate drivers GD1 and GD2 may be provided in the non-active area NA so as to be connected to gate lines GL1, GL2, . . . of the active area AA, and the data driver DD may be provided in the non-active area NA so as to be connected to data lines DL1, DL2, . . . of the active area AA. The gate drivers GD1 and GD2 and/or the data driver DD may be integrated and provided in the first substrate 100 or may be attached to the first substrate 100 by a printed circuit film. For example, the gate drivers GD1 and GD2 may be integrated and provided in the form of a gate in panel (GIP) within the first substrate 100, and may sequentially supply gate voltages to the gate lines GL1, GL2, . . . disposed in the active area AA. The gate drivers GD1 and GD2 may be formed together in the same stack or through the same process as the wirings and transistors within the active area AA. The data driver DD may be disposed in a part of the non-active area NA of the first substrate 100 by attaching a printed circuit film including a drive IC to the firs substrate 100.

The gate lines GL1, GL2, . . . may be disposed, for example, in a first direction (the X-axis direction), and the data lines DL1, DL2, . . . may be disposed, for example, in a second direction (the Y-axis direction).

In the respective subpixels SP, the data lines DL1, DL2, . . . and first power voltage lines VSL1, VSL2, . . . may be alternately arranged, as shown in FIG. 1. However, the transparent display device 1000 according to an example embodiment of the present disclosure is not limited thereto. One first power voltage line may be disposed per subpixel SP in the first direction (the X-axis direction). In addition, as shown in FIG. 1, the first power voltage lines VSL1, VSL2, . . . may be disposed in a second direction, but are not limited thereto and may be arranged in the first direction. In some cases, the first power voltage lines VSL1, VSL2, . . . may be arranged to intersect in the first and second directions.

Further, the Z-axis direction is a direction in which an array configuration is formed on the first substrate 100. The Z-axis direction may be the height direction of the spacers GS of FIG. 3 and FIG. 4.

The gate drivers GD1 and GD2 and the data driver DD may be connected to an external printed circuit board through LOG (line on glass) wirings and/or connectors. The printed circuit board may be folded toward the rear surface of the first substrate 100.

The active area AA is an area that displays an image. In the active area AA of the display panel DP, as shown in FIG. 2, the plurality of subpixels SP are arranged between the gate lines GL and the data lines DL that intersect each other, and an image may be displayed using the plurality of subpixels SP.

At least one subpixel SP among the plurality of subpixels SP may include a first transistor SW, a second transistor DR, a storage capacitor Cst, a compensation circuit CC, and a light emitting element ED, as shown in FIG. 2.

For example, the first transistor SW may be a switching transistor, and the second transistor DR may be a driving transistor.

A first source/drain electrode (e.g., a drain electrode) of the first transistor SW is conductively connected to the data line DL, and a second source/drain electrode (e.g., a source electrode) of the first transistor SW is conductively connected to a first node N1. A gate electrode of the first transistor SW is conductively connected to the gate line GL. The first transistor SW transmits a data signal supplied through the data line DL to the first node N1 in response to a scan signal supplied through the gate line GL.

The storage capacitor Cst is conductively connected to the first node N1 and is charged with a voltage applied to the first node N1.

A first source/drain electrode (e.g., a drain electrode) of the second transistor DR receives a high-potential driving voltage EVDD, and a second source/drain electrode (e.g., a source electrode) of the second transistor DR is conductively connected to a first electrode (e.g., an anode) of the light emitting element ED. The second transistor DR may control the amount of driving current flowing to the light emitting element ED in response to a voltage applied to a gate electrode.

A second electrode (e.g., a cathode) of the light emitting element ED may receive a low-potential driving voltage EVSS through the first power voltage line VSL. The low-potential driving voltage EVSS may be a common voltage applied commonly to all the subpixels SP. In addition, the first source/drain electrode of the second transistor DR may receive a high-potential driving voltage EVDD through a second power voltage line VDL.

One first power voltage line VSL and one second power voltage line VDL may be disposed per each subpixel SP, or may be disposed regularly per a plurality of subpixels SP.

A semiconductor layer of the first transistor SW and/or the second transistor DR may include silicon, such as amorphous silicon (a-Si), polycrystalline silicon (poly-Si), or low-temperature polycrystalline silicon (poly-Si), or may include an oxide, such as indium-gallium-zinc-oxide (IGZO), but is not limited thereto. At least one of the first transistor SW and the second transistor DR may include an oxide semiconductor layer to be formed at a relatively low temperature compared to other materials, maintain amorphous characteristics, and have high mobility.

The light emitting element ED outputs light corresponding to the driving current. The light emitting element ED may output light corresponding to one of red, green, blue, and white.

The light emitting element ED may include the first electrode, an intermediate layer disposed on the first electrode, and the second electrode supplying a common voltage. The intermediate layer includes an emission layer and a common layer, and the emission layer may be implemented to emit light of the same color, such as white light, for each subpixel SP, or may be implemented to emit a different color, such as red, green, or blue light, for each subpixel SP.

The light emitting element ED may be a top-emission diode or a bottom-emission diode.

The first electrode of the light emitting element ED may be connected to the second transistor DR, and the second electrode of the light emitting element ED may be connected to the first power voltage line VSL. The transparent display device 1000 according to an example embodiment of the present disclosure may have an auxiliary connection portion ACT between the first power voltage line VSL and the second electrode of the light emitting element ED in each subpixel SP or in some of the subpixels SP. In addition, in the transparent display device 1000 according to an example embodiment of the present disclosure, the auxiliary connection portion ACT between the first power voltage line VSL and the second electrode of the light emitting element ED is generated in an island structure BS on the first substrate 100, and the spacer GS supporting the cell gap is located on the island structure BS.

The compensation circuit CC may be provided in the subpixel SP to compensate for the threshold voltage of the second transistor DR, etc. The compensation circuit CC may include one or more transistors. The compensation circuit CC may include one or more transistors and capacitors, and may be configured in various ways depending on a compensation method. The subpixel including the compensation circuit CC may include one of circuits of various structures having different numbers of transistors and/or capacitors, such as 3T1C, 4T2C, 5T2C, 6T1C, 6T2C, 7T1C, and 7T2C. In the transparent display device of embodiments of the present disclosure, the circuit of the subpixel SP is not limited to the number of transistors and/or the number of capacitors.

Hereinafter, corresponding configurations of the island structure BS and the spacer GS in the transparent display device of embodiments of the present disclosure will be specifically described.

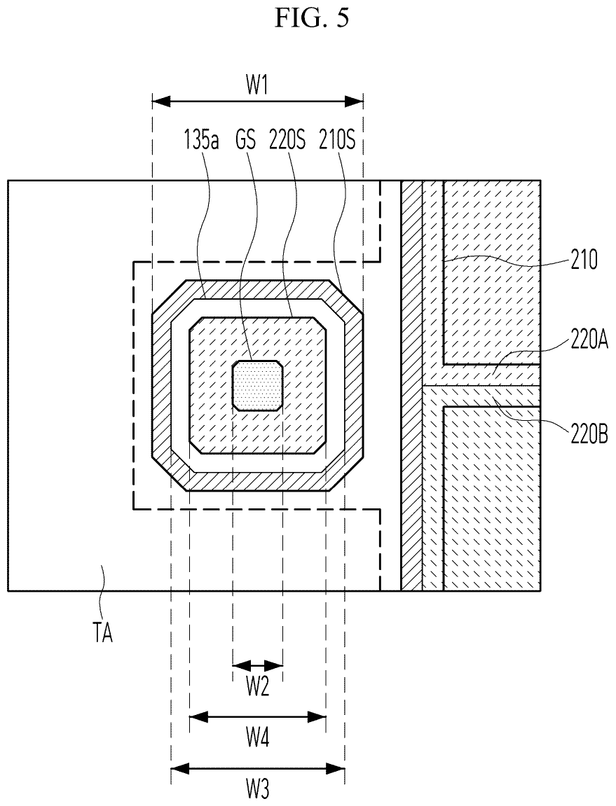

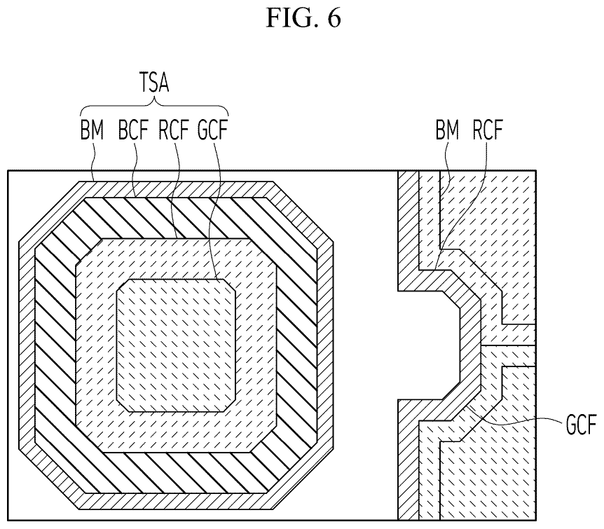

FIG. 3 is a partial enlarged view of the active area, particularly, an enlarged view of region A of FIG. 1, according to an example embodiment of the present disclosure, and FIG. 4 is a cross-sectional view taken along line I-I′ of FIG. 3. FIG. 5 is a plan view showing upper and lower structures corresponding to the spacer of FIG. 4. FIG. 6 is a plan view showing a spacer structure formed of an upper substrate structure and an adjacent upper substrate structure.

If the light emitting element ED has the common layer in the intermediate layer formed without a deposition mask having an opening for each subpixel SP, as shown in FIGS. 3 to 5, the island structure BS may be provided on the first power voltage line VSL so as to separate the common layer, and direct connection between a second electrode 153 and the first power voltage line VSL may be achieved through a region where the common layer region is separated around the island structure BS.

Specifically, the transparent display device according to an example embodiment of the present disclosure, as shown in FIGS. 1 to 5, includes the first substrate 100 having the active area AA including an emission area EA and a transmission area TA, and the non-active area NA around the active area AA, a first power voltage lines VSL spaced apart from the transmission area TA, . . . within the active area AA of the first substrate 100, light emitting elements ED provided in the emission area EA, island structures BS provided on the first power voltage lines VSL and spaced apart from at least an intermediate layer 152 of the light emitting elements ED, the second substrate 200 facing the first substrate 100, and spacers GS, each of which is located on at least a part of a corresponding one of the island structures BS and provided between the first substrate 100 and the second substrate 200. But is not limited thereto. For example, the active area AA may include a plurality of emission areas EA1, EA2, EA3, EA4, . . . and a plurality of transmission areas TA1, TA2. One of a plurality of first power voltage lines VSL may be spaced apart from a correspond one of the plurality of transmission areas. A plurality of light emitting elements ED may be provided in the plurality of emission areas. A plurality of island structures may be provided on the plurality of first power voltage lines and a plurality of spacers may be located on the plurality of island structures.

The spacers GS include a cross-linking component of a cross linker at a certain density or more in a monomer or polymer, and may thus easily control patterning to have a width equal to or less than the width of the island structures BS, preferably, smaller than a width of an uppermost surface of the island structure BS, and have constant restoring force and excellent elasticity after patterning. Therefore, even if external pressure is applied from the outside of the first substrate 100 or the second substrate 200, the spacers GS supporting the cell gap have constant support and elasticity, and are thus prevented or suppressed from being severely deformed due to the external pressure and are easily restored to the original state after the external pressure is relieved.

The spacers GS may include an organic material. The spacers GS included in the array configuration on the first substrate 100 and the second substrate 200 have a high cross linker density and thus a high aspect ratio compared to organic materials included in the array configuration on the first substrate 100 and the second substrate 200. That is, the spacers GS may be patterned with a smaller width and greater height than the organic materials included in the array configuration on the first and second substrates 100 and 200, for example, an overcoat layer or a light shielding layer, and has excellent elasticity and restoring force against external pressure.

The light emitting element ED disposed at least in the emission area EA may include the first electrode 151, the intermediate layer 152, and the second electrode 153.

For example, when the emission area EA of the transparent display device is a front emission type, the first electrode 151 may include a reflective electrode, and the second electrode 153 may include a transparent electrode or a transflective electrode.

The first electrode 151 may include a stacked structure of a reflective electrode and a transparent electrode at the interface between the first electrode 151 and the intermediate layer 152 to lower an interface barrier when injecting holes. For example, the reflective electrode may include silver (Ag), a silver alloy, such as APC (Ag—Pd—Cu), aluminum (Al), or an aluminum alloy. The transparent electrode may be a transparent oxide electrode including ITO or IZO.

The second electrode 153 may be formed by thinning a transparent electrode including ITO or IZO, or a transflective electrode including silver, a silver alloy, magnesium, a magnesium alloy, ytterbium (Yb), or an ytterbium alloy.

The emission area EA of the light emitting element ED may be defined as an open area of a bank 160. The bank 160 may be disposed in areas between the plurality of emission areas EA1, EA2, EA3, EA4, . . . and areas between the emission areas EA1, EA2, EA3, EA4, . . . and the transmission areas TA1, TA2, . . . . Areas where the island structures BS are disposed and the bank 160 may be spaced apart from each other.

FIG. 4 shows an example in which the intermediate layer 152 and the second electrode 153 are commonly provided in the transmission areas TA, but embodiments of the present disclosure are not limited thereto. In another embodiment of the present disclosure, at least one of the intermediate layer 152 and the second electrode 153 may be removed from the transmission areas TA or may be absent in the transmission area TA to increase transmittance in the transmission areas TA.

Further, the light emitting element ED may be connected to one of transistors TFT provided in the pixel circuit of the subpixel.

As shown in FIG. 4, the transistor TFT may include, for example, an active layer 122 on the first substrate 100, a gate electrode 131 partially overlapping the active layer 122, and a first source/drain electrode 141 and a second source/drain electrode 142 connected to the active layer 122.

The transistor TFT may be connected to the first electrode 151 of the light emitting element ED.

For example, the first electrode 151 of the light emitting element ED may be connected to the second source/drain electrode 142 of the transistor TFT through a contact hole formed through a fourth insulating layer 126 formed of an inorganic insulating layer component that covers and protects the transistor TFT, and an overcoat layer 135 formed of an organic insulating material and disposed on the fourth insulating layer 126. An example in which the first electrode 151 penetrates the overcoat layer 135 and the fourth insulating layer 126 is illustrated, but embodiments of the present disclosure are not limited thereto. If the overcoat layer 135 has a two-layer structure including a lower overcoat layer and an upper overcoat layer, a connection electrode connected to the second source/drain electrode 142 of the transistor TFT that penetrates the fourth insulating layer 126 and the lower overcoat layer may be disposed, and the first electrode 151 may be connected to the connection electrode through a contact hole that penetrates the upper overcoat layer.

Although not illustrated in FIG. 4, a light shielding metal pattern may be further included in an area that overlaps at least a channel region of the active layer 122 under the active layer 122 of the transistor TFT. The light shielding metal pattern may prevent or suppress light coming from below the first substrate 100 from affecting the active layer 122. Here, at least one insulating layer may be disposed between the light shielding metal pattern and the active layer 122.

A first insulating layer 121 functioning as a buffer layer may be provided between the first substrate 100 and the active layer 122.

The active layer 122 may include at least one of an oxide semiconductor, amorphous silicon, and crystalline silicon. When the active layer 122 includes an oxide semiconductor, the active layer 122 may include a plurality of oxide semiconductor layers having different mobilities.

A gate insulating layer 123 may be provided between the active layer 122 and the gate electrode 131.

Second and third insulating layers 124 and 125 are further disposed between the gate electrode 131 and the first and second source/drain electrodes 141 and 142 and may function to insulate the electrodes. The second and third insulating layers 123 and 124 may be provided as a single layer, in some cases.

The fourth insulating layer 126 formed of an inorganic insulating layer component and the overcoat layer 135 formed of an organic insulating layer component may be provided on the first and second source/drain electrodes 141 and 142 on the first substrate 100. The fourth insulating layer 126 and the overcoat layer 135 may have a function of protecting the transistor TFT. In addition, the fourth insulating layer 126 and the overcoat layer 135 that serve as a protective layer may be patterned as the island structure BS on the first power voltage line VSL so as to be spaced apart from the surroundings. In addition, the overcoat layer 135 may be removed from the transmission area TA to increase the transmittance of the transmission area TA.

The example illustrated in FIG. 4 shows that the first insulating layer 121, the gate insulating layer 123, the second insulating layer 124, the third insulating layer 125, and the fourth insulating layers 126 are provided as a single layer, but at least one thereof may include a plurality of inorganic insulating layers. The inorganic insulating layer may be, for example, one of a silicon oxide layer, a silicon oxynitride layer, and a silicon nitride layer.

In addition, the example illustrated in FIG. 4 shows a single transistor, but this is an example, and other transistors may be included in the subpixel. In addition, some of a plurality of transistors may have the same configuration, and others have a different stack by changing the layered structure of one of the active layer, the gate electrode, or one of the first and second source/drain electrodes among the configuration of the transistors from the structure illustrated in FIG. 4.

In addition, the first power voltage line VSL may be disposed in the same layer as at least one electrode of the transistor TFT. As shown in FIG. 3, the first power voltage line VSL is arranged to be spaced apart from the transmission areas TA: TA1, TA2, . . . . The first power voltage line VSL may overlap the emission areas EA. Since the first power voltage line VSL is formed of metal wiring and does not transmit light passing through the first substrate 100, the first power voltage line VSL is disposed so as not to overlap the transmission areas TA for improving the transmittance of the transmission areas TA.

In the illustrated example, the first power voltage line VSL is disposed in the same layer as the first and second source/drain electrodes 141 and 142 of the transistor TFT, but embodiments of the present disclosure are not limited thereto. The first power voltage line VSL may be disposed in the same layer as the gate electrode or the light shielding metal pattern disposed under the active layer 122.

The island structure BS is disposed on the first power voltage line VSL and is located between the emission area EA and the transmission area TA. The reason why the island structure BS is spaced apart from the emission area EA and the transmission area TA is to prevent or reduce influence of exposure the intermediate layer 152 on the island structure BS or around the island structure BS. In addition, an area of the first power voltage line VSL where the island structure BS is disposed may be an area between the emission area EA and the transmission area TA rather than an area between the emission areas EA: EA1, EA2, EA3, EA4, . . . . For this purpose, the first power voltage line VSL may be disposed such that a portion of the first power voltage line VSL protrudes toward the transmission area TA1 to form an auxiliary connection portion ACT between the first power voltage line VSL and the second electrode 153. Although a portion of the intermediate layer 152 exists in the transmission areas TA: TA1, TA2, . . . , the portion of the intermediate layer 152 is not directly used for light emission, and therefore, even if the portion of the intermediate layer 152 remaining in the transmission areas TA: TA1, TA2, . . . is damaged, the damage to the portion of the intermediate layer 152 does not affect the transmittance.

In some cases, the intermediate layer 152 may be omitted from the transmission areas TA: TA1, TA2, . . . .

In the emission areas EA: EA1, EA2, EA3, EA4, . . . , light is directly emitted from the intermediate layer 152, the intermediate layer 152 is separated from dummy patterns of the island structure BS around the island structure BS, and the area of the first power voltage line VSL where the intermediate layer 152 is not formed is connected to the second electrode 153. If the separated portion of the intermediate layer 152 is located between the emission areas EA: EA1, EA2, EA3, EA4, . . . , adjacent emission areas may be affected by moisture permeation occurring at the disconnection portion of the intermediate layer 152 between the adjacent emission areas. Therefore, the transparent display device of an example embodiment of the present disclosure forms the first power voltage line VSL having a protrusion that protrudes toward the transmission area TA rather than in an area between the emission areas EA: EA1, EA2, EA3, EA4, . . . , as shown in FIG. 3, thereby forming an auxiliary connection portion ACT at the protrusion of the first power voltage line VSL. In addition, the island structure BS may be disposed on the protrusion of the first power voltage line VSL so as to prevent or suppress disconnection of the intermediate layer 152 between the emission areas EA: EA1, EA2, EA3, EA4, . . . . Through separation between the intermediate layer 152 which is the component of the emission area EA and a dummy intermediate layer 152a of the island structure BS, even if an area where some of structures are absent to expose the first power voltage line VSL is vulnerable to moisture permeation, the influence of disconnection of the intermediate layer 152 may be prevented or suppressed from being transmitted to the emission areas EA: EA1, EA2, EA3, EA4, . . . .

The auxiliary connection portion ACT at the protrusion of the first power voltage line VSL may have a region where the intermediate layer 152 is not formed due to the strong straightness of an intermediate layer material in the deposition process of the intermediate layer material around the island structure BS, and the second electrode 153 having a relatively higher step coverage than the intermediate layer material may be disposed adjacent to the island structure BS in this region where the intermediate layer 152 is not formed, thereby enabling direct connection between the first power voltage line VSL and the second electrode 153.

The island structure BS may be formed by stacking a dummy inorganic layer 126a formed in the same layer as the fourth insulating layer 126 and an overcoat layer 135a formed in the same layer as the overcoat layer 135, which are adjacent components disposed in the emission area EA. The stack of the dummy inorganic layer 126a and the dummy overcoat layer 135a may be referred to as a basic configuration of the island structure BS.

The dummy overcoat layer 135a may protrude relatively farther outward than the dummy inorganic layer 126a of the island structure BS, and the dummy overcoat layer 135a may form an overhang structure with respect to the dummy inorganic layer 126a. An outer edge of the dummy inorganic layer 126a that is farther inward than that of the dummy overcoat layer 135a may be provided by undercutting.

The fourth insulating layer 126 and the overcoat layer 135 on the first substrate 100 may be spaced apart from the outer perimeter of the island structure BS, and a portion of the first power voltage line VSL may be exposed around the island structure BS.

The overcoat layer 135 may have a greater thickness than the fourth insulating layer 126 formed of an inorganic material, and may secure a region having a certain height and a high vertical phase independently from the surrounding overcoat layer 135 in the island structure BS formed of the dummy overcoat layer 135a of the same layer as the overcoat layer 135. Therefore, in the case in which the dummy inorganic layer 126a is located under the dummy overcoat layer 135a to be farther inward than the outer edge of the dummy overcoat layer 135a, when the second electrode 153 is formed, the second electrode 153 may partially enter a region under the dummy overcoat layer 135 where the dummy inorganic layer 126a is removed or absent, and may be connected to the first power voltage line VSL.

The fourth insulating layer 126 around the island structure BS may have a greater region overlapping the first power voltage line VSL than the overcoat layer 135. In this case, the undercut region located at the lower part of the island structure BS may be formed in a separate process from the patterning process of the overcoat layer 135.

The intermediate layer 152 including the common layer that is deposited with straightness with respect to structures on the first substrate 100 may not be formed at least in the undercut region of the dummy inorganic layer 126a at the lower part of the island structure BS due to the undercut shape of the dummy inorganic layer 126a in the island structure BS.

The intermediate layer 152 includes, for example, a hole injection layer, a hole transport layer, an emission layer, an electron transport layer, and an electron injection layer, and at least one of these layers may be formed as a common layer without distinction for each subpixel. In some cases, at least one of the hole transport layer and the electron transport layer may be formed with a different thickness or a different layer structure to have a different resonance effect depending on an emitted light color exhibited by the subpixel. In addition, one emission layer may be provided between the hole transport layer and the electron transport layer, but a plurality of emission layers may be provided by changing one of a host and a dopant. The intermediate layer 152 may include a plurality of stacks and a charge generation layer between the plurality of stacks, in some cases. Here, one stack may be provided as one unit including a hole transport layer, an emission layer, and an electron transport layer, so that each stack may include one unit.

At least one component included in the intermediate layer 152 may be provided as a common layer corresponding to at least the active area AA without a mask that distinguishes the respective subpixels SP, and the configuration of the intermediate layer 152 provided as the common layer may be discontinuous around the island structure BS without using a separate mask. That is, the intermediate layer 152 is formed on the upper surface and a part of the side surface of the island structure BS, but may not be formed below the region where the dummy overcoat layer 135a of the island structure BS protrudes farther outward than the dummy inorganic layer 126a.

Materials forming the intermediate layer 152 may include an organic material. The intermediate layer 152 is formed by disposing the first substrate 100 in a chamber so that a surface thereof, on which the intermediate layer 152 will be formed, faces downward, and supplying a vaporized deposition material from below to the surface of the first substrate 100 to be sublimated to form a thin layer in a deposition process. During the sublimation process, since the deposition material is adhered to the first substrate 100 with straightness, the deposition material may not be deposited in a region where the island structure BS is disposed, particularly, in a gap with the dummy inorganic layer 126a located under the dummy overcoat layer 135a.

The second electrode 153 provided on the intermediate layer 152 includes a metal material and has better step coverage than the intermediate layer 152 including an organic material, and may thus cover the intermediate layer 152 and be deposited closer to the dummy inorganic layer 126a of the island structure BS than the intermediate layer 152, and therefore, the second electrode 153 may have a direct connection with the first power voltage line VSL in a part of the region below the dummy overcoat layer 135a. Here, a common voltage may be supplied to the second electrode 153 within the active area AA through the auxiliary connection portion ACT between the second electrode 153 and the first power voltage line VSL around the island structure BS. Therefore, a common voltage may be supplied to the second electrode 153 formed integrally over the entire active area AA at the edge of the second electrode 153 in the non-active area NA, and a common voltage may be directly supplied to the second electrode 153 through the first power voltage line VSL passing through the active area AA in the active area AA, thereby being capable of preventing or suppressing a decrease in brightness in the central region of the active area AA that is far from a common power supply.

These auxiliary connections portion ACT may be arranged at uniform intervals over the entire active area AA. For example, one auxiliary connection portion ACT may be provided per subpixel, or may be provided per a plurality of subpixels SP.

The dummy intermediate layer 152a formed in the same layer as the intermediate layer 152 may be further provided on upper and side portions of the island structure BS, and a dummy electrode layer 153a formed in the same layer as the second electrode 153 may be further provided on the upper and side portions of the dummy intermediate layer 152a.

In addition, a lower protective layer 170 may be further provided on the uppermost surface of the first substrate 100. The lower protective layer 170 may be provided not only in the active area AA but also in the non-active area NA as a transparent inorganic insulating layer to prevent or suppress moisture or external air permeation. For example, the lower protective layer 170 may comprise a silicon nitride layer, a silicon oxynitride layer, a silicon oxide layer, a metal oxide layer, or a metal nitride layer.

A dummy lower protective layer 170a formed of the same material as the lower protective layer 170 may be further provided on the island structure BS. The lower protective layer 170 formed around the island structure BS at the lower portion of the island structure BS, particularly, in the region where the dummy overcoat layer 135a protrudes farther outward than the dummy inorganic layer 126a, may be formed to extend to the lower portion of the island structure BS and cover the second electrode 153. In this case, the lower protective layer 170 may partially contact the first power voltage line VSL. Therefore, the second electrode 153 and the lower protective layer 170 located at the lower portion of the island structure BS may be formed to cover and protect the intermediate layer 152, thereby being capable of preventing or suppressing organic materials, such as the intermediate layer 152, from being exposed in the emission area EA located around the island structure BS and preventing or suppressing moisture permeation. The lower protective layer 170 may have discontinuous portions in a region between the emission area and the transmission area where the first power voltage line is disposed.

The intermediate layer 152, the second electrode 153, and the lower protective layer 170 may be formed at least over the entire active area AA without using a deposition mask having an opening for each subpixel, but may be spaced apart from the island structure BS around the island structure BS due to the undercut shape of the island structure BS on the first power voltage line VSL. That is, the intermediate layer 152, the second electrode 153, and the lower protective layer 170 are spaced apart from the dummy intermediate layer 152a, the dummy electrode layer 153a, and the dummy lower protective layer 170a of the island structure BS.

The island structure BS has a stack of the dummy inorganic layer 126a and the dummy overcoat layer 135a as a basic configuration for separation of the intermediate layer 152, but may further include the dummy intermediate layer 152a, the dummy electrode layer 153a, and the dummy lower protective layer 170a that are formed on the dummy overcoat layer 135a and are separated from the surrounding intermediate layer 152, the second electrode 153, and the lower protective layer 170.

The transparent display device according to embodiments of the present disclosure may not increase the height of the spacers GS supporting the cell gap between the first and second substrates 100 and 200 by disposing the spacers GS on the island structures BS which have a relatively high vertical phase and are independently disposed on the first substrate 100, thereby enabling a spacer structure to be easily formed. In addition, since the width of the spacers GS may be limited to a width within the planar area occupied by the island structures BS, a process margin for forming the spacers GS supporting the cell gap may be omitted, and thus, it may be relatively easy to secure the transmission areas, thereby being capable of improving the transmittance of the transparent display device.

Further, the second substrate 200 facing the first substrate 100 is provided with color filters 220A corresponding to the emission area EA. Different color filters 220A may correspond to adjacent emission areas EA1, EA2, EA3, and EA4.

The bank 160 that partially overlaps the edge of the first electrode 151 may be provided in areas between the plurality of emission areas EA1, EA2, EA3, and EA4 on the first substrate 100. The bank 160 may be disposed in the areas between the emission areas EA1, EA2, EA3, and EA4 and the transmission areas TA: TA1 and TA2, and may be disposed not to interfere with the island structure BS and an area around the island structure BS to provide the auxiliary connection portion ACT between the first power voltage line VSL and the second electrode 153.

The bank 160 may include one of a transparent bank and an opaque bank, or may include a stack of a transparent bank and an opaque bank. In the transmission area TA, the bank 160 may be omitted to improve transmittance. A transparent display device according to another embodiment of the present disclosure may include a bank material in the island structure BS so as to sufficiently secure the height of the island structure BS.

A light shielding layer 210 may be disposed on the second substrate 200 to face the bank 160.

An upper protective layer 230 may be disposed on one surface of the second substrate 200 corresponding to the surface of the first substrate 100 on which the light emitting elements ED and the island structures BS are formed, so as to cover the light shielding layer 210 and the color filters 220A. Further, the color filters 220A may be provided as color filters that transmit the wavelength of each color, for example, when the emission areas EA1, EA2, EA3, and EA4 transmit light of different colors, as shown in FIG. 3. For example, if first to third emission areas EA1, EA2, and EA3 display red, green, and blue, respectively, and a fourth emission area EA4 displays white, the first to third emission areas EA1, EA2, and EA3 may include red, green, and blue color filters, respectively, and the fourth emission area EA4 may not include a color filter. Alternatively, the fourth emission area EA4 may further include a transparent film having the same or similar thickness to the surrounding color filters to prevent or suppress a step on one surface of the second substrate 200.

The upper protective layer 230 may be a transparent inorganic insulating layer which is provided on the entire surface of the second substrate 200, and may have a function of covering and protecting the internal configurations of the light shielding layer 210 and the color filters 220A. Since the upper protective layer 230 is disposed on the entire surface of the second substrate 200, the upper protective layer 230 does not require a mask during formation.

Further, in an area of the second substrate 200 corresponding to the spacer GS, an upper structure TS including a light shielding pattern 210S of the same layer as the light shielding layer 210, a color filter pattern 220S of the same layer as the color filters 210A, and the upper protective layer 230 covering the color filter pattern 220S is disposed.

The light shielding pattern 210S and the color filter pattern 220S forming the upper structure TS may have a greater width than the spacer GS.

Among the components of the upper structure TS, a first width W1, which is a width of at least one of the light shielding pattern 210S and the color filter pattern 220S, may be greater than a third width W3, which is a width of the island structure BS.

FIG. 4 shows an example in which a patterned configuration of the upper structure TS includes a two-layer configuration including the light shielding pattern 210S and the color filter pattern 220S, but the transparent display device of embodiments of the present disclosure is not limited thereto. Only a single-layer configuration of the light shielding pattern 210S or the color filter pattern 220S may be patterned and included in the upper structure TS.

In the patterned configuration of the upper structure TS, the first width W1, which is the maximum width, may be greater than a second width W2, which is the maximum width of the spacer GS, and may also be greater than the third width W3, which is the maximum width of the island structure BS. In particular, a width of a surface of the upper structure TS closest to the spacer GS may be greater than the width of the uppermost surface of the island structure BS. As long as the upper structure TS is spaced apart from the transmission area TA and the emission area EA, the upper structure TS does not affect light emission or transmittance. The upper structure TS is designed with a degree of freedom so that the first width W1 of the upper structure TS is greater than the third width W3 of the island structure BS, and the disposition of the spacer GS may be limited only within the third width W3 of the island structure BS.

In the illustrated example, the light shielding pattern 210S is illustrated as having the first width W1 and the color filter pattern 220S is illustrated as having a smaller width than the first width W1. In this case, since the first width W1 of the light shielding pattern 210S is greater than the third width W3 which is the maximum width of the island structure BS, the color filter pattern 220S is easily disposed on one surface of the wide and flat light shielding pattern 210. In addition, the island structure BS located closer to the spacer GS than the color filter pattern 220S may be implemented with a high aspect ratio, so that the spacer GS may be easily disposed with a narrower width than the upper surface of the island structure BS.

The spacer GS corresponds to the upper structure TS disposed in an area having the greatest thickness among the array configuration on the second substrate 200 and corresponds to the island structure BS independently having a relatively high vertical phase on the first substrate 100, so that the spacer GS is disposed between the areas of both first and second substrates 100 and 200 with high vertical phases. Therefore, the thickness of the spacer GS may be reduced, and the cell gap may be lowered.

A gap between the lower protective layer 170 on the first substrate 100 and the upper protective layer 230 of the second substrate 200 may be filled with a filler 250.

The first width W1 of the light shielding pattern 210S having the greatest width may be greater than the second width W2 of the spacer GS, and may also be greater than the third width W3 which is the greatest width of the island structure BS.

Each of the lower protective layer 170 located on the uppermost surface of the first substrate 100 and the upper protective layer 230 located on the lowermost surface of the second substrate 200 is a transparent insulating layer, and is formed of a material that does not reduce the transmittance of the transmission area TA. A thickness of the upper protective layer may be smaller than a thickness of each of the first layer, the second layer, and the spacer.

A material forming the spacer GS is an organic material including a cross linker, and has a higher density and better elasticity and resilience than the compositions of other organic material layers provided in the transparent display device 1000. Therefore, the spacer GS may be designed to have a high aspect ratio when patterned, and the spacer GS between the upper structure TS and the island structure BS is located between the lower surface of the upper protective layer 230 and the upper surface of the dummy lower protective layer 170a. The spacer GS may be disposed in direct contact with the lower surface of the upper protective layer 230 and the dummy lower protective layer 170a without including any other separate components.

The transparent display device 1000 according to embodiments of the present disclosure allows the spacers GS to correspond to the island structures BS independently having a high vertical phase on the first substrate 100 so that the spacers GS support the first substrate 100 and the second substrate 200 facing each other, thereby being capable of minimizing or reducing the cell gap between the first and second substrates 100 and 200 and minimizing or reducing the effect of damage to the dummy lower protective layer 170a in contact with the spacer GS. That is, even if the dummy lower protective layer 170a is provided as the uppermost component of the island structure BS and the spacer GS is in contact with the dummy lower protective layer 170a, the dummy lower protective layer 170a of the island structure BS may be separated from the lower protective layer 170 around the island structure BS. Therefore, even if a part of the dummy lower protective layer 170a in contact with the spacer GS is damaged during bonding, crack propagation to the lower protective layer 170 does not occur, and thus, a decrease in the moisture permeability due to damage to the dummy lower protective layer 170a may be prevented or suppressed.

The transparent display device 1000 according to embodiments of the present disclosure uses the spacers GS whose width and thickness are easy to control, so that the spacers GS having the smaller width than the island structures BS may be provided, and the provision of the spacers GS does not affect the arrangement of the transmission areas TA. In addition, in a structure where the cell gap is supposed by the stacked structure of a plurality of color filter patterns, the dimensions of the transmission areas TA may be increased compared to a structure having a large process margin of the maximum width in consideration of misalignment of the patterns.

The transparent display device 1000 shown in FIGS. 4 and 5 is an example of a structure in which the light shielding pattern 210S has the maximum width (first width W1) in the upper structure TS, but embodiments of the present disclosure are not limited thereto. In some cases, a fourth width, which is a fourth width W4 of the color filter pattern 220S, may be greater than the first width W1 of the light shielding pattern 210S.

As shown in FIG. 4, the fourth width W4 of the color filter pattern 220S that is in contact with one surface of the light shielding pattern 210S and is located closer to the spacer GS than the light shielding pattern 210S may be smaller than the first width W1 of the light shielding pattern 210S.

In the transparent display device according to embodiments of the present disclosure, the fourth width W4 of the color filter pattern 220S may be greater than the width W3 of the island structure BS which is the maximum width of the island structure BS, as shown in FIG. 4, or may be smaller than the third width W3 of the island structure BS, as shown in FIG. 5. The fourth width W4 of the color filter pattern 220S may be changed as long as the fourth width W4 of the color filter pattern 220S is smaller than the first width W1 of the light shielding pattern 210S and greater than the second width W2 of the spacer GS.

The transmission area TA may be adjacent to the light shielding pattern 210S, and in some cases, the outer line of the transmission area TA may coincide with the edge of the light shielding pattern 210S. In this case, the dimensions of the transmission area TA may be increased, and the transmittance may be improved. In addition, it is possible to reduce the first width W1 of the light shielding pattern 210S corresponding to the island structure BS, and thus the dimensions of the transmission area TA may be increased. This may be confirmed more clearly through comparison of FIGS. 5 and 6.

As illustrated in FIG. 6, an example in which an upper structure TSA is formed using only components on a second substrate (upper substrate) is shown.

As shown in FIG. 6, when the upper structure TSA having a cell gap support function is formed by stacking a light shielding layer BM, a blue color filter BCF, a red color filter RCF, and a green color filter GCF, the planar area of the upper structure TSA increases in consideration of misalignment between the layers of the upper structure TSA.

In addition, the upper structure TSA is configured to provide support between the first and second substrates, and to avoid damage to components on the first substrate facing the upper structure TSA due to bonding, the upper structure TSA must be spaced apart from an emission area, as shown in FIG. 6. For this purpose, the light shielding layer BM disposed at the edge of the emission area may be spaced apart from the upper structure TSA, and the dimensions of the emission area may be reduced.

Therefore, when forming the upper structure TSA with the components on the second substrate of FIG. 6, an area occupied by the upper structure TSA increases, a distance between the upper structure TSA and the light shielding layer BM at the edge of the emission area is required, and thus, a decrease in the dimensions of the transmission area may occur.

On the other hand, compared to the case of forming the upper structure TSA including the stack of the components of the second substrate of FIG. 6, particularly the plurality of color filter patterns, the structure in which the spacer supports the cell gap between the first and second substrates of the present disclosure of FIG. 5 makes it easy to control the width and thickness (height) of the spacer due to physical properties thereof. In addition, in the transparent display device according to embodiments of the present disclosure, since the spacer GS whose width and height are easy to control performs the cell gap support function, the first width W1 of the upper structure TS which is the maximum width of the upper structure TS may be reduced, and also, since the number of patterned components of the upper structure TS is reduced, there is no need to increase the width in consideration of an alignment margin. Therefore, the transparent display device according to embodiments of the present disclosure has the effect of significantly increasing the dimensions of the transmission areas TA by an area shown by a dotted line, as in FIG. 5, compared to the structure of FIG. 6, which forms the spacer structure using only the components on the second substrate.

In addition, in a structure in which a cell gap between the first and second substrates is large and thus the cell gap is not secured using only components of the second substrate, a spacer structure may be formed by further patterning an upper overcoat layer, thereby being capable of preventing or suppressing uneven filling of a filler in respective regions due to the increase in the cell gap.

In the transparent display device according to embodiments of the present disclosure, the upper structure TS is sufficient to secure a certain thickness in a region corresponding to the spacer GS, and may prevent or suppress an increase in a cell gap and propagation of a crack caused by adhesion of an organic material in a structure in which an overcoat layer is provided on the uppermost surface of the upper structure TS and is patterned to support the cell gap.

In addition, the transparent display device according to embodiments of the present disclosure allows the upper structure TS on the second substrate corresponding to the spacer GS to include a light shielding layer and a single color filter pattern instead of a stack of a plurality of color filter patterns, thereby being capable of reducing an area and height occupied by the upper structure TS. Therefore, a light shielding area considering an alignment margin between the first and second substrates may be reduced, and the transmission areas may be expanded.

The transparent display device according to embodiments of the present disclosure allows the island structure BS on the first substrate 100 or the upper structure TS of the second substrate 200 facing the island structure BS to be patterned on each substrate, and has the lower or upper protective layer 170 or 230 formed of an inorganic insulating material on the uppermost surface of each substrate 100 or 200, thereby being capable of omitting use of a separate mask using the lower or upper protective layer 170 or 230 formed of the inorganic insulating material on the entire surface of the first or second substrate 100 or 200. Therefore, the yield may be improved by reducing the number of masks.

The transparent display device according to embodiments of the present disclosure allows the upper protective layer 230 formed of the inorganic insulating material to be formed on the entire surface of the second substrate 200, thereby being capable of strengthening a function of preventing or suppressing moisture permeation throughout the entire surface of the active area and further helping reduce the cell gap.

The transparent display device according to embodiments of the present disclosure allows the spacer GS disposed between the island structure BS and the upper structure TS to support the cell gap, and may thus reduce the cell gap. Accordingly, a required amount of the filler 250 that fills a vertical space between the first and second substrates 100 and 200 may be reduced. In addition, since the spacer GS may be disposed to have a width smaller than the width of each of the island structure BS and the upper structure TS, supply amounts of materials used throughout the manufacturing process, such as deposition gas and an etching solution to manufacture the display device, may be reduced, thereby being capable of reducing greenhouse gases generated during the manufacturing process and enabling process optimization. Such process optimization may reduce environmental pollution, contribute to sustainability, and implement environmental, social, and governance (ESG).

Further, the arrangement of the spacers GS within the active area AA may vary depending on the embodiment. Hereinafter, embodiments depending on the arrangement of the spacers GS within the active area AA will be described.

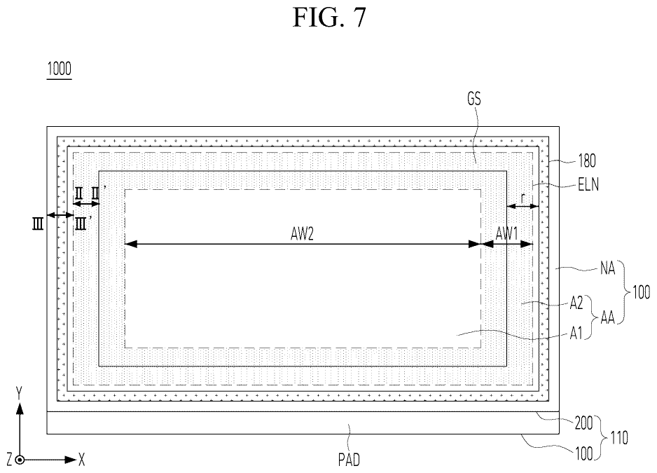

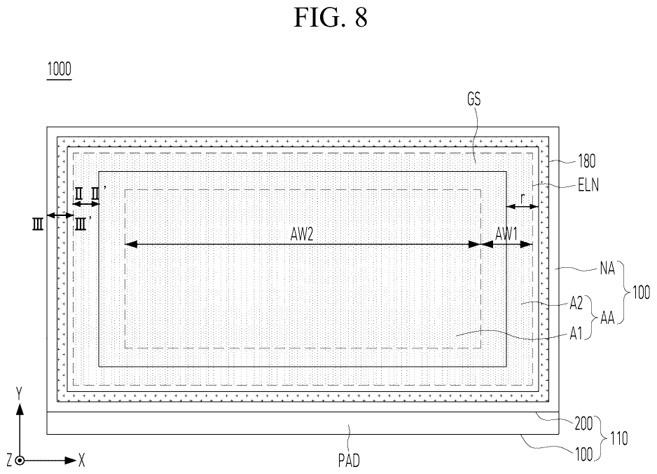

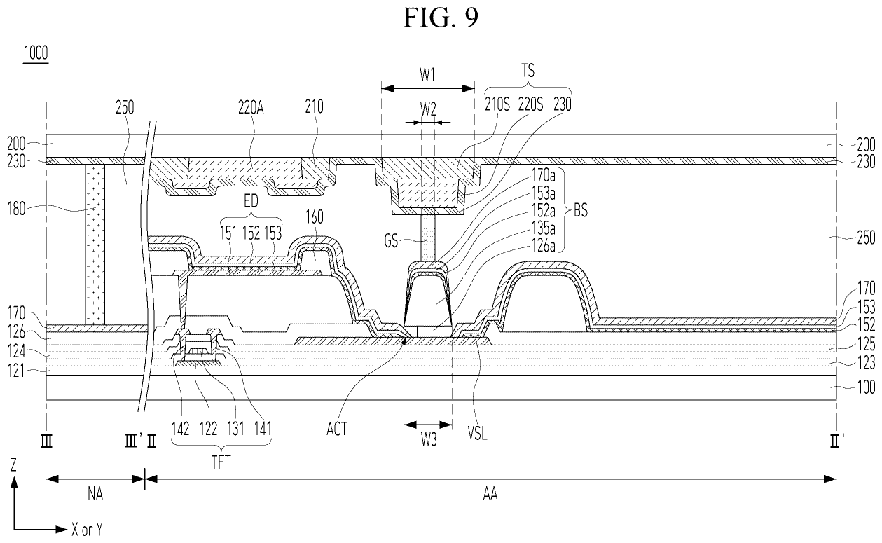

FIG. 7 is a plan view showing a transparent display device according to a first example embodiment of the present disclosure. FIG. 8 is a plan view showing a transparent display device according to a second example embodiment of the present disclosure. FIG. 9 is a cross-sectional view taken along line II-II′ and line III-III′ of FIG. 7 or FIG. 8 together.

As shown in FIGS. 7 and 9, in the transparent display device according to the first example embodiment of the present disclosure, spacers GS providing support between island structures BS on a first substrate 100 and upper structures TS on a second substrate 200 may be disposed in at least a second area A2 located within a first distance AW1 from an edge line ELN of an active area AA, of the active area AA. In this case, the spacers GS may not be provided in a first area A1 located in the central region of the active area AA.

Here, in the second area A2, one spacer GS may be disposed per subpixel or may be disposed corresponding to a plurality of subpixels.

As such, the reason for locally disposing the spacers GS is to resolve problems caused by non-filling of a filler near the edge line ELN of the active area AA that occur when the dotting process of a filler material is performed in a region spaced apart from a dam pattern 180.

As shown in FIG. 7, in the process of filling a space between the first and second substrates 100 and 200 with the filler 250 (in FIGS. 4 and 9), the filler material is first dotted in a plurality of areas spaced apart from each other on one substrate, and then the first and second substrates 100 and 200 are bonded. After a predetermined period of time, the filler material is diffused and evenly filled between the first and second substrates 100 and 200. The dam pattern 180 for bonding between the first and second substrates 100 and 200 is disposed in the non-active area NA of the first substrate 100 or the second substrate 200, and during the dotting process of the filler material, since the dam pattern 180 is not cured, dotting of the filler material is performed in areas spaced inwardly apart from the dam pattern 180 by a predetermined distance r to avoid interference between the filler material and the dam pattern 180.

In this case, in a structure having a large cell gap between the first and second substrates 100 and 200, an unfilled area where the filler material is not present may occur between the dam pattern 180 where the filler material is not dotted and the outermost dotting area of the filler material.

The transparent display device according to an example embodiment of the present disclosure has an area, in which the filler material is not initially dotted within the predetermined distance r from the dam pattern 180 at the initial stage of dotting of the filler material, and further includes the spacers GS (see FIGS. 3 and 4) providing support between the first and second substrates 100 and 200 within the first distance AW1, from an edge line ELN of the active area AA greater than the predetermined distance r between the dam pattern 180 and the initial dotting edge of the filler material, thereby inserting the island structures BS, the spacers GS, and upper structures TS that are components vertically connected in a continuous manner to support the cell gap, into the active area AA, thereby being capable of minimizing or reducing occurrence of non-filling of the filler material near the edge line ELN, and even if there are some areas which are not filled with the filler material, enabling the spacers GS having the cell gap support function to provide stable support between the first and second substrates 100 and 200, and thus preventing or suppressing the cell gap from being reduced or having severe fluctuations near the edge line ELN of the active area AA.

Further, as described in FIGS. 3 to 5, the spacers GS are located between the island structures BS independently having a high vertical phase on the first substrate 100 and the upper structures TS on the second substrate 200 that faces the island structure BS.

In addition, the dam pattern 180 is provided in the non-active area NA between the first and second substrates 100 and 200 to support the cell gap between the first and second substrates 100 and 200 at the edges of the first and second substrates 100 and 200. After the bonding of the first and second substrates 100 and 200, the dam pattern 180 may be cured, and then the filler 250 may be diffused to come into contact with the dam pattern 180.

Further, the dam pattern 180 may be disposed to be in contact with the upper surface of the lower protective layer 170 on the first substrate 100 and the lower surface of the upper protective layer 230 on the second substrate 200. A height of the dam pattern 180 may be greater than a sum of a height of the upper structure TS and a height of the spacer GS, and is less than a sum of the height of the upper structure TS, the height of the spacer GS, and a height of the island structure BS.

The transparent display device according to embodiments of the present disclosure may implement uniformity in the low cell gap based on the dam pattern 180 to enhance optical issues, and may improve transparency without increasing the number of masks. The lower protective layer 170 and the upper protective layer 230, which are the uppermost layers disposed on the first substrate 100 and the second substrate 200, may be provided as transparent inorganic insulating layers that do not require patterning, respectively, to reduce the number of masks and minimize or reduce the influence of internal moisture permeation.

Further, as an example shown in FIG. 7, a pad portion PAD may be provided on an area of the first substrate 100 that protrudes more than the second substrate 200. The pad portion PAD may be located farther outward the dam pattern 180 and be connected to an external printed circuit board.

FIG. 8 is a plan view showing the transparent display device according to the second example embodiment of the present disclosure.

As shown in FIGS. 8 and 9, the transparent display device according to the second embodiment of the present disclosure has spacers GS evenly arranged throughout the active area AA. In this case, one spacer GS may be disposed per subpixel, or may be disposed corresponding to a plurality of subpixels.

The transparent display device according to the second embodiment of the present disclosure has the spacers GS for supporting the cell gap between first and second substrates that are evenly arranged throughout the active area AA, so that the cell gap is evenly maintained by the spacers GS, thereby preventing or suppressing the cell gap in the entire active area AA from fluctuating.

In FIG. 8, island structures BS in the first area A1 and the second area A2 may correspond to the spacers GS to support the cell gap, and correspondence between the island structures BS and the spacers GS may follow the above-described structure of FIG. 9.

The transparent display device including transmission areas needs to arrange various wirings and transistors in an area that does not overlap the transmission areas to increase transmittance.

A transparent display device may be manufactured by, for example, bonding a first substrate having wirings and transistors and a second substrate having color filters. In the transparent display device, a configuration for maintaining a cell gap must be designed to be spaced apart from the transmission areas and have a certain process margin or more from the transmission areas in consideration of occurrence of misalignment between the first and second substrates, and this configuration may cause a decrease in transmittance. The transparent display device according to embodiments of the present disclosure allows spacer structures that easily adjust an aspect ratio between the first and second substrates facing each other to be inserted within the active area to reduce the thickness of a filler between the first and second substrates, thereby being capable of reducing the cell gap and simultaneously preventing or suppressing non-filling or overfilling of the filler within the cell gap.

The transparent display device according to embodiments of the present disclosure allows the island structures in areas on the first substrate corresponding to the spacer structures, thereby being capable of preventing, reducing, or minimizing influence on the configuration around the island structures even if a crack occurs in the protective layer when the spacer structures and the uppermost surface of the first substrate meet.

The transparent display device according to embodiments of the present disclosure may have the island structure including the overcoat layer for connection between the first power voltage line and the second electrode in the active area on the first substrate and allow the island structure to have a certain height or more, thereby being capable of reducing the width and thickness of the spacer structure corresponding to the island structure.

The transparent display device according to embodiments of the present disclosure allows the spacer structures to have a smaller width than the width of the island structures to secure the transmission areas without affecting the size of the spacer structures for maintaining the cell gap, and furthermore, may reduce the width of the island structures to the level of the width of the spacer structures to increase the dimensions of the transmission area adjacent to the island structure.

The transparent display device according to embodiments of the present disclosure may control the cell gap through the height of the spacer structures, so that the upper protective layer disposed on the second substrate may be an inorganic protective layer capable of being formed on the entire surface of the second substrate, thereby being capable of reducing the number of masks and thus achieving process optimization.

The transparent display device according to embodiments of the present disclosure may have the spacers disposed between the first and second substrates within at least a certain distance from the edge line of the active area within the active area so as to maintain the cell gap between the first and second substrates, and even if the filler is applied to an area spaced apart from the dam pattern by a certain distance, may prevent or suppress local non-filling of the filler and uniformly maintain the cell gap throughout the entire active area. That is, occurrence of non-filling and overfilling of the filler may be prevented or suppressed.

In addition, the transparent display device according to embodiments of the present disclosure allows the spacers to correspond to the island structures independently having a great height on the first substrate so that the spacers support the first and second substrates facing each other, thereby being capable of minimizing or reducing the cell gap between the first and second substrates and minimizing or reducing the effect of damage to the lower protective layer in contact with the spacers. That is, even if the lower protective layer is provided on the island structures and the spacers are in contact with the lower protective layer, the lower protective layer on the island structures may be separated from the lower protective layer around the island structures. Therefore, even if a partial area of the lower protective layer in contact with the spacers is damaged, deterioration in moisture permeability due to crack propagation of the lower protective layer may be prevented or suppressed.

The transparent display device according to embodiments of the present disclosure may use the spacers whose width and thickness are easy to control and allow the spacers to have a smaller width than the width of the island structures, so that provision of the spacers does not affect arrangement of the transmission areas, thereby being capable of maximizing or increasing the dimensions of the transmission areas.

The upper structures on the second substrate corresponding to the spacers are configured to include a light shielding layer and a single color filter rather than a stack of a plurality of color filters, thereby being capable of reducing the area and height occupied by the upper structures. Accordingly, a light shielding area considering an alignment margin between the first and second substrates may be reduced, and the transmission areas may be expanded.

In the transparent display device according to embodiments of the present disclosure, island structures on the first substrate or the upper structures of the second substrate facing the island structures may be patterned on each substrate, and a protective layer of an inorganic insulating material may be provided on the uppermost surface of each substrate. Thus, use of a separate mask by forming the protective layer of the inorganic insulating material over the entire surface of the first or second substrate may be omitted. Therefore, the yield may be improved by reducing the number of masks.

The transparent display device according to an example embodiment of the present disclosure may include an upper protective layer over the entire surface of the second substrate, the upper protective layer comprises an inorganic insulating material the second substrate. Thus, the transparent display device according to an example embodiment of the present disclosure can strengthen a function of preventing or suppressing moisture permeation and further help reduce the cell gap.

The transparent display device according to an example embodiment of the present disclosure may reduce use of a required filler that is vertically filled between the first and second substrates by reducing the cell gap, and allow the spacers with a smaller width than the width of each of the island structures and the upper structures. Accordingly, supply amounts of materials used throughout a manufacturing process, such as deposition gas and an etching solution to manufacture the display device, may be reduced, thereby being capable of reducing greenhouse gases generated during the manufacturing process and enabling process optimization. Such process optimization may reduce environmental pollution, contribute to sustainability, and implement environmental, social, and governance (ESG).

A transparent display device according to an example embodiment of the present disclosure may comprise a first substrate having an active area comprising an emission area and a transmission area, and a non-active area around the active area, a plurality of power voltage lines spaced apart from the transmission area within the active area of the first substrate, a light emitting element at the emission area, an island structure provided on each of the plurality of power voltage lines and spaced apart from an intermediate layer of the light emitting element, a second substrate facing the first substrate and a spacer located on at least a portion of the island structure, and provided between the first substrate and the second substrate.

In a transparent display device according to an example embodiment of the present disclosure, the spacer may be between the emission area and the transmission area and the spacer may be disposed at a higher density at an edge region of the active area than a center region of the active area.

In a transparent display device according to an example embodiment of the present disclosure, the spacer may be arranged within a first distance from an edge line of the active area. The active area may comprise a center area having a greater distance than the first distance and configured such that the spacer is not arranged therein.

In a transparent display device according to an example embodiment of the present disclosure, the spacer may be arranged at an equal interval throughout the active area.

A transparent display device according to an example embodiment of the present disclosure may further comprise an upper structure comprising at least one of a light shielding pattern and a color filter pattern at a region of a first surface of the second substrate configured to face the spacer.

In a transparent display device according to an example embodiment of the present disclosure, a width of the spacer may be smaller than a width of an uppermost surface of the island structure.

In a transparent display device according to an example embodiment of the present disclosure, the emission area may comprise a plurality of emission areas configured to emit light of different colors, a light shielding layer between the plurality of emission areas and a color filter corresponding to each of the plurality of emission areas on a first surface of the second substrate facing the first substrate and an upper protective layer to cover the light shielding layer and the color filter on the first surface of the second substrate.

A transparent display device according to an example embodiment of the present disclosure further comprise an upper structure including a first layer at a same layer as the light shielding layer and a second layer at a same layer as the color filter corresponding the spacer between the second substrate and the upper protective layer.

In a transparent display device according to an example embodiment of the present disclosure, the upper protective layer may comprise an inorganic insulating material.

In a transparent display device according to an example embodiment of the present disclosure, a thickness of the upper protective layer may be smaller than a thickness of each of the first layer, the second layer, and the spacer.

A transparent display device according to an example embodiment of the present disclosure further comprise a lower protective layer located at an uppermost surface of the first substrate. One surface of the spacer may be in contact with the upper protective layer and another surface of the spacer may be in contact with the lower protective layer.

In a transparent display device according to an example embodiment of the present disclosure, each of the lower protective layer and the upper protective layer may comprise a transparent inorganic insulating layer.

In a transparent display device according to an example embodiment of the present disclosure, the light emitting element may comprise a first electrode and a second electrode with the intermediate layer interposed therebetween. The second electrode may be spaced apart from the island structure and may be connected to one of the plurality of power voltage lines around the island structure.

In a transparent display device according to an example embodiment of the present disclosure, the island structure may comprise an inorganic insulating layer pattern and an overcoat layer pattern on the inorganic insulating layer pattern to protrude farther outward than the inorganic insulating layer pattern.

In a transparent display device according to an example embodiment of the present disclosure, the island structure may further comprise a dummy intermediate layer at a same layer as the intermediate layer, a dummy electrode layer at a same layer as the second electrode, and a lower protective layer pattern at a same layer as the lower protective layer, on the overcoat layer pattern.

A transparent display device according to an example embodiment of the present disclosure may comprise an inorganic insulating layer on the first substrate around the island structure to be spaced apart from the island structure and an overcoat layer on the inorganic insulating layer corresponding to the emission areas. The overcoat layer may be absent at the transmission area.

A transparent display device according to an example embodiment of the present disclosure further may comprise a dam pattern between the first substrate and the second substrate at the non-active area. A height of the dam pattern may be greater than a sum of a height of the upper structure and a height of the spacer, and is less than a sum of the height of the upper structure, the height of the spacer, and a height of the island structure.

In a transparent display device according to one embodiment of the present disclosure, the power voltage line may be disposed such that a portion of the power voltage line protrudes toward the transmission area to form an auxiliary connection on which the island structure is disposed.

In a transparent display device according to one embodiment of the present disclosure, the island structure may further include a bank material on the dummy overcoat layer.

A transparent display device according to an example embodiment of the present disclosure may comprise a first substrate having an active area comprising an emission area and a transmission area, and a non-active area around the active area, a plurality of power voltage lines spaced apart from the transmission area within the active area of the first substrate, a light emitting element at the emission area, an island structure on one of the plurality of power voltage lines and spaced apart from an intermediate layer of the light emitting element, a second substrate facing the first substrate and a spacer located on the island structure and provided within the active area between the first substrate and the second substrate at a higher density on an edge region of the active area than a center region of the active area.

A transparent display device according to an example embodiment of the present disclosure may further comprise an upper structure comprising at least one of a light shielding pattern and a color filter pattern on a first surface of the second substrate to face the spacer, an upper protective layer to cover the upper structure on an entirety of the first surface of the second substrate and a lower protective layer over an uppermost surface of the first substrate.

In a transparent display device according to an example embodiment of the present disclosure, each of the upper protective layer and the lower protective layer may comprise a transparent inorganic insulating layer.

In a transparent display device according to an example embodiment of the present disclosure, the lower protective layer may have discontinuous portions at a region between the emission area and the transmission area where one of the plurality of power voltage lines is disposed.

In a transparent display device according to an example embodiment of the present disclosure, one surface of the spacer may be in contact with the upper protective layer, and another surface of the spacer may be in contact with the lower protective layer.

In a transparent display device according to an example embodiment of the present disclosure, a width of the spacer may be smaller than a width of an uppermost surface of the island structure. A width of surface of the upper structure closest to the spacer may be greater than the width of the uppermost surface of the island structure.

In a transparent display device according to an example embodiment of the present disclosure, the light emitting element may comprise a first electrode and a second electrode with the intermediate layer interposed therebetween. The second electrode may be spaced apart from the island structure and may be connected to one of the plurality of power voltage lines around the island structure.

As is apparent from the above description, a transparent display device according to an example embodiment of the present disclosure has the following effects.

First, spacers are disposed between first and second substrates within at least a certain distance from an edge line of an active area within the active area to maintain a cell gap between first and second substrates, and even if a filler is applied to an area spaced apart from a dam pattern by a certain distance, local non-filling of the filler may be prevented or suppressed, and the cell gap throughout the entire active area may be uniformly used. That is, occurrence of non-filling and overfilling of the filler may be prevented or suppressed.

Second, the spacers are disposed to correspond to island structures independently having a great height on the first substrate so that the spacers provide support between the first and second substrates facing each other, thereby being capable of minimizing or reducing the cell gap between the first and second substrates and minimizing or reducing the effect of damage to a lower protective layer in contact with the spacers. That is, even if the lower protective layer is provided on the island structures and the spacers are in contact with the lower protective layer, the lower protective layer provided on the island structures may be separated from the lower protective layer around the island structures. Therefore, even if a partial area of the lower protective layer in contact with the spacers is damaged, deterioration in moisture permeability due to crack propagation of the lower protective layer may be prevented or suppressed, and the reliability of the configuration of emission areas adjacent to the island structures may be improved.

Third, the spacers whose width and thickness are easy to control are used and thus the spacers may have a smaller width than the width of the island structures, so that provision of the spacers does not affect arrangement of transmission areas, thereby being capable of maximizing or increasing the dimensions of the transmission areas.

Fourth, upper structures on the second substrate corresponding to the spacers include a light shielding layer and a single color filter rather than a stack of a plurality of color filters, thereby being capable of reducing an area and height occupied by the upper structures. Accordingly, a light shielding area considering an alignment margin between the first and second substrates may be reduced, and the transmission areas may be expanded.

Fifth, the island structures on the first substrate or the upper structures of the second substrate facing the island structures are patterned on each substrate, and a protective layer formed of an inorganic insulating material is provided on the uppermost surface of each substrate, thereby being capable of omitting use of a separate mask by forming the protective layer of the inorganic insulating material over the entire surface of the first or second substrate. Therefore, the yield may be improved by reducing the number of masks.

Sixth, an upper protective layer on the second substrate is formed of an inorganic insulating material over the entire surface of the second substrate, thereby being capable of strengthening a function of preventing or suppressing moisture permeation and further helping reduce the cell gap.

Seventh, the transparent display device according to an example embodiment of the present disclosure may reduce use of a required filler that is vertically filled between the first and second substrates by reducing the cell gap, and allow the spacers with a smaller width that the width of each of the island structures and the upper structures. Accordingly, supply amounts of materials used throughout a manufacturing process, such as deposition gas and an etching solution to manufacture the display device, may be reduced, thereby being capable of reducing greenhouse gases generated during the manufacturing process and enabling process optimization. Such process optimization may reduce environmental pollution, contribute to sustainability, and implement environmental, social, and governance (ESG).

Through the above description, it should be apparent to those skilled in the art that various changes and modifications are possible without departing from the technical spirit of the present disclosure. Therefore, the technical scope of the present disclosure should not be limited to the above detailed description, but should be considered to encompass the full scope of the claims and their equivalents.

What is claimed is:

1. A transparent display device, comprising:
a first substrate having an active area comprising an emission area and a transmission area, and a non-active area around the active area;
a plurality of power voltage lines spaced apart from the transmission area within the active area of the first substrate;
a light emitting element at the emission area;
an island structure provided on each of the plurality of power voltage lines and spaced apart from at least an intermediate layer of the light emitting element;
a second substrate facing the first substrate; and
a spacer located on at least a portion of the island structure, and provided between the first substrate and the second substrate.

2. The transparent display device according to claim 1, wherein the spacer is between the emission area and the transmission area, and the spacer is disposed at a higher density at an edge region of the active area than at a center region of the active area.

3. The transparent display device according to claim 1, wherein:
the spacer is arranged within a first distance from an edge line of the active area; and
the active area comprises a center area having a greater distance than the first distance and configured such that the spacer is not arranged therein.

4. The transparent display device according to claim 1, wherein the spacer is arranged at an equal interval throughout the active area.

5. The transparent display device according to claim 1, further comprising an upper structure comprising at least one of a light shielding pattern and a color filter pattern at a region of a first surface of the second substrate configured to face the spacer.

6. The transparent display device according to claim 1, wherein a width of the spacer is smaller than a width of an uppermost surface of the island structure.

7. The transparent display device according to claim 1, wherein:
the emission area comprises a plurality of emission areas configured to emit light of different colors;
a light shielding layer between the plurality of emission areas and a color filter corresponding to each of the plurality of emission areas on a first surface of the second substrate facing the first substrate; and
an upper protective layer to cover the light shielding layer and the color filter on the first surface of the second substrate.

8. The transparent display device according to claim 7, further comprising an upper structure including a first layer at a same layer as the light shielding layer and a second layer at a same layer as the color filter corresponding the spacer between the second substrate and the upper protective layer.

9. The transparent display device according to claim 7, wherein the upper protective layer comprises an inorganic insulating material.

10. The transparent display device according to claim 8, wherein a thickness of the upper protective layer is smaller than a thickness of each of the first layer, the second layer, and the spacer.

11. The transparent display device according to claim 8, further comprising a lower protective layer located at an uppermost surface of the first substrate,
wherein one surface of the spacer is in contact with the upper protective layer, and another surface of the spacer is in contact with the lower protective layer.

12. The transparent display device according to claim 11, wherein each of the lower protective layer and the upper protective layer comprises a transparent inorganic insulating layer.

13. The transparent display device according to claim 11, wherein:
the light emitting element comprises a first electrode and a second electrode with the intermediate layer interposed therebetween; and
the second electrode is spaced apart from the island structure and is connected to one of the plurality of power voltage lines around the island structure.

14. The transparent display device according to claim 13, wherein the island structure comprises an inorganic insulating layer pattern and an overcoat layer pattern on the inorganic insulating layer pattern to protrude farther outward than the inorganic insulating layer pattern.

15. The transparent display device according to claim 14, wherein the island structure further comprises a dummy intermediate layer at a same layer as the intermediate layer, a dummy electrode layer at a same layer as the second electrode, and a lower protective layer pattern at a same layer as the lower protective layer, on the overcoat layer pattern.

16. The transparent display device according to claim 14, further comprising:
an inorganic insulating layer on the first substrate around the island structure to be spaced apart from the island structure; and
an overcoat layer on the inorganic insulating layer corresponding to the emission areas,
wherein the overcoat layer is absent at the transmission area.

17. The transparent display device according to claim 8, further comprising a dam pattern between the first substrate and the second substrate at the non-active area,
wherein a height of the dam pattern is greater than a sum of a height of the upper structure and a height of the spacer, and is less than a sum of the height of the upper structure, the height of the spacer, and a height of the island structure.

18. A transparent display device, comprising:
a first substrate having an active area comprising an emission area and a transmission area, and a non-active area around the active area;
a plurality of power voltage lines spaced apart from the transmission area within the active area of the first substrate;
a light emitting element at the emission area;
an island structure on one of the plurality of power voltage lines and spaced apart from an intermediate layer of the light emitting element;
a second substrate facing the first substrate; and
a spacer located on the island structure and provided within the active area between the first substrate and the second substrate at a higher density at an edge region of the active area than at a center region of the active area.

19. The transparent display device according to claim 18, further comprising:
an upper structure comprising at least one of a light shielding pattern and a color filter pattern on a first surface of the second substrate to face the spacer;
an upper protective layer to cover the upper structure on an entirety of the first surface of the second substrate; and
a lower protective layer over an uppermost surface of the first substrate.

20. The transparent display device according to claim 19, wherein each of the upper protective layer and the lower protective layer comprises a transparent inorganic insulating layer.

21. The transparent display device according to claim 19, wherein the lower protective layer has discontinuous portions at a region between the emission area and the transmission area where one of the plurality of power voltage lines is disposed.

22. The transparent display device according to claim 19, wherein one surface of the spacer is in contact with the upper protective layer, and another surface of the spacer is in contact with the lower protective layer.

23. The transparent display device according to claim 19, wherein:
a width of the spacer is smaller than a width of an uppermost surface of the island structure; and
a width of surface of the upper structure closest to the spacer is greater than the width of the uppermost surface of the island structure.

24. The transparent display device according to claim 19, wherein:
the light emitting element comprises a first electrode and a second electrode with the intermediate layer interposed therebetween; and
the second electrode is spaced apart from the island structure and is connected to one of the plurality of power voltage lines around the island structure.
